(19) United States
(12) Patent Application Publication
(10) Pub. No.: US 2025/0075107 A1
(43) Pub. Date: Mar. 6, 2025

(54) ADHESIVE COMPOSITION AND DISPLAY APPARATUS INCLUDING THE SAME

(71) Applicant: Samsung Display Co., Ltd., Yongin-Si (KR)

(72) Inventors: Bookan Ki, Yongin-si (KR); Hoyun Byun, Yongin-si (KR); Jeongin Lee, Yongin-si (KR); Seongsik Choi, Yongin-si (KR)

(21) Appl. No.: 18/674,508

(22) Filed: May 24, 2024

(30) Foreign Application Priority Data
Aug. 29, 2023 (KR) 10-2023-0113739

(51) Int. Cl. C09J 7/38; C09J 4/06; H05K 5/00; H05K 5/03

(52) U.S. Cl. CPC C09J 7/383; C09J 4/06; H05K 5/0018; H05K 5/03; C09J 2203/326; C09J 2409/00; C09J 2425/00

(57) ABSTRACT

An adhesive composition is disclosed that includes styrene, polybutadiene, sulfurous ester, isopropenyl toluene, and methylphenylacetylene. A cured product of the adhesive composition has a relative permittivity of at least about 2.0 but not more than about 2.5 wt %. Using the adhesive composition as an antenna film adhesive layer between a display panel and an antenna film or between a functional layer and the antenna film may provide a small thickness of the adhesive layer and improved reliability of a touch sensor and an antenna.

### CROSS-REFERENCE TO RELATED APPLICATION

This application is based on and claims priority under 35 U.S.C. § 119 to Korean Patent Application No. 10-2023-0113739, filed on Aug. 29, 2023, in the Korean Intellectual Property Office, the disclosure of which is incorporated by reference herein in its entirety.

### BACKGROUND

### 1. Field

Embodiments relate to an adhesive composition and a display apparatus including the adhesive composition.

### 2. Description of the Related Art

Recently, the use of display apparatuses has diversified. In addition, as the display apparatuses become thinner and lighter, the range of use of the display apparatuses has become widespread. As the range of use of the display apparatuses has become diversified, various methods have been studied to design the shapes of the display apparatuses.

A display apparatus may receive an input of information from the outside through a touch input by a user on a display screen equipped with a touch sensor. Furthermore, the display apparatus may transmit and receive wireless communication signals through an antenna. An optically clear adhesive is used for adhesion between the components of the display apparatus. An optically clear adhesive is required to basically have good moisture resistance, heat resistance, and adhesive quality along with good optical characteristics.

However, in display apparatus in the related art, performances of a touch sensor and an antenna may be reduced due to interference that occurs between the touch sensor and the antenna. To prevent this problem in the related art, the thickness of an optically clear adhesive between the touch sensor and the antenna must be thick.

### SUMMARY

One or more embodiments may provide an adhesive composition that, when used in a display apparatus, may provide an adhesive layer having a thin thickness while improving the reliability of a touch sensor and an antenna.

Additional aspects will be set forth in part in the description which follows and, in part, will be apparent from the description, or may be learned by practice of the presented embodiments of the disclosure.

According to one or more embodiments, an adhesive composition includes styrene, polybutadiene, sulfurous ester, isopropenyl toluene, and methylphenylacetylene, wherein a cured product of the adhesive composition has a relative permittivity of at least about 2.0 but not more than about 2.5.

A content of the styrene may be at least about 35 wt % but not more than about 50 wt %, a content of the polybutadiene may be at least about 10 wt % but not more than about 20 wt %, a content of the sulfurous ester may be at least about 15 wt % but not more than about 25 wt %, a content of the isopropenyl toluene may be at least about 5 wt % but not more than about 15 wt %, and a content of the methylphenylacetylene may be at least about 3 wt % but not more than about 10 wt %.

The polybutadiene may include cis-1,4-polybutadiene, the sulfurous ester may include sulfurous acid, cyclohexylmethyl dodecyl ester, the isopropenyl toluene may include p-isopropenyl toluene, and the methylphenylacetylene may include 3-methylphenylacetylene.

The adhesive composition may further include an antioxidant, wherein a content of the antioxidant may be at least about 3 wt % but not more than about 10 wt %.

The adhesive composition may further include a plasticizer, wherein a content of the plasticizer may be at least about 0.5 wt % but not more than about 2 wt %.

According to one or more embodiments, a display apparatus includes a display panel including a touch sensor layer, an antenna film disposed over the display panel and including an antenna, a functional layer disposed over the antenna film, a cover window disposed over the functional layer, and an antenna film adhesive layer between the display panel and the antenna film, wherein the antenna film adhesive layer includes a cured product of an adhesive composition, the adhesive composition including styrene, polybutadiene, sulfurous ester, isopropenyl toluene, and methylphenylacetylene, wherein the antenna film adhesive layer has a relative permittivity of at least about 2.0 but not more than about 2.5 wt %.

A content of styrene may be at least about 35 wt % but not more than about 50 wt %, a content of the polybutadiene may be at least about 10 wt % but not more than about 20 wt %, a content of the sulfurous ester may be at least about 15 wt % but not more than about 25 wt %, a content of the isopropenyl toluene may be at least about 5 wt % but not more than about 15 wt %, and a content of the methylphenylacetylene may be at least about 3 wt % but not more than about 10 wt %.

The polybutadiene may include cis-1,4-polybutadiene, the sulfurous ester may include sulfurous acid, cyclohexylmethyl dodecyl ester, the isopropenyl toluene may include p-isopropenyl toluene, and the methylphenylacetylene may include 3-methylphenylacetylene.

The adhesive composition may further include an antioxidant, wherein a content of the antioxidant may be at least about 3 wt % but not more than about 10 wt %.

The adhesive composition may further include a plasticizer, wherein a content of the plasticizer may be at least about 0.5 wt % but not more than about 2 wt %.

In a plan view, the touch sensor layer and the antenna may be arranged adjacent to each other.

The functional layer may include a polarization film.

The functional layer may include at least one of polyethersulfone, polyacrylate, polyetherimide, polyethylene naphthalate, polyethylene terephthalate, polyphenylene sulfide, polyimide, polycarbonate, and cellulose acetate propionate.

According to one or more embodiments, a display apparatus includes a display panel including the touch sensor layer, a functional layer disposed over the display panel, an antenna film disposed over the functional layer and including an antenna, a cover window disposed over the antenna film, and an antenna film adhesive layer between the functional layer and the antenna film, wherein the antenna film adhesive layer includes a cured product of an adhesive composition, the adhesive composition includes styrene, polybutadiene, sulfurous ester, isopropenyl toluene, and methylphenylacetylene, wherein the antenna film adhesive layer has a relative permittivity of at least about 2.0 but not more than about 2.5 wt %.

A content of the styrene may be at least about 35 wt % but not more than about 50 wt %, a content of the polybutadiene may be at least about 10 wt % but not more than about 20 wt %, a content of the sulfurous ester may be at least about 15 wt % but not more than about 25 wt %, a content of the isopropenyl toluene may at least about 5 wt % but not more than about 15 wt %, and a content of the methylphenylacetylene may be at least about 3 wt % but not more than about 10 wt %.

The polybutadiene may include cis-1,4-polybutadiene, the sulfurous ester may include sulfurous acid, cyclohexylmethyl dodecyl ester, the isopropenyl toluene may include p-isopropenyl toluene, and the methylphenylacetylene may include 3-methylphenylacetylene.

The adhesive composition may further include an antioxidant, wherein a content of the antioxidant may be at least about 3 wt % but not more than about 10 wt %.

The adhesive composition may further include a plasticizer, wherein a content of the plasticizer may be at least about 0.5 wt % but not more than about 2 wt %.

In a plan view, the touch sensor layer and the antenna may be arranged adjacent to each other

The functional layer may include a polarization film.

The functional layer may include at least one of polyethersulfone, polyacrylate, polyetherimide, polyethylene naphthalate, polyethylene terephthalate, polyphenylene sulfide, polyimide, polycarbonate, and cellulose acetate propionate.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a cross-sectional view of the display apparatus of FIG. 1, taken along a line A-A′

FIG. 3 is a schematic plan view of a display panel of a display apparatus according to an embodiment;

FIG. 4 is an equivalent circuit diagram schematically illustrating a pixel circuit of a display panel and a display element connected to the pixel circuit;

FIG. 5 is a schematic cross-sectional view of the display panel of FIG. 3, taken along a line B-B′;

FIG. 6 is a schematic plan view of an antenna film of a display apparatus according to an embodiment;

FIG. 7 is a schematic cross-sectional view of the antenna film of FIG. 6, taken along a line C-C′; and

FIG. 8 is a schematic cross-sectional view of a display apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

In the disclosure, while such terms as “first,” “second,” etc., may be used to describe various elements, such elements must not be limited to the above terms.

In the disclosure, an expression used in the singular encompasses the expression of the plural, unless it has a clearly different meaning in the context.

In the disclosure, it is to be understood that the terms such as “including” and “having” are intended to indicate the existence of the features, or elements disclosed in the present disclosure, and are not intended to preclude the possibility that one or more other features or elements may exist or may be added.

It will be understood that when a layer, region, or component is referred to as being “formed on” another layer, region, or component, it can be directly or indirectly formed on the other layer, region, or component, for example, intervening layers, regions, or components may be present.

In the disclosure, it will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

In the present disclosure, the x axis, the y axis, and the z axis are not limited to three rows on the orthogonal coordinates system, and may be interpreted in a broad sense including the same. For example, the x axis, the y axis, and the z axis may be perpendicular to one another, or may represent different directions that are not perpendicular to one another.

In the disclosure, “in a plan view” means that an object part is viewed from above. That is, in the disclosure, “in a plan view” may mean “when viewed from a direction perpendicular to a substrate 100.”

The disclosure will now be described more fully with reference to the accompanying drawings, in which embodiments of the disclosure are shown. Like reference numerals in the drawings denote like elements, and thus their description will be omitted. Sizes of components in the drawings may be exaggerated for convenience of explanation. In other words, since sizes and thicknesses of components in the drawings are arbitrarily illustrated for convenience of explanation, the following embodiments are not limited thereto.

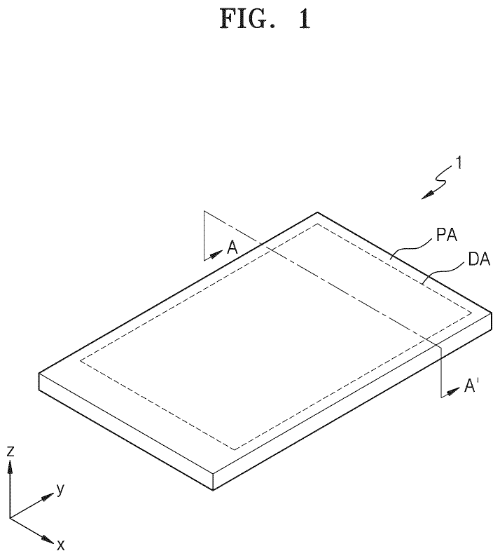

FIG. 1 is a schematic perspective view of a display apparatus 1 according to an embodiment.

The display apparatus 1 is an apparatus which displays a video or a still image, and may be a portable electronic device, such as a mobile phone, a smart phone, a tablet personal computer (PC), a mobile communication terminal, an electronic notebook, an electronic book, a portable multimedia player (PMP), a navigation device, an Ultra Mobile PC (UMPC), or the like. The display apparatus 1 may also be an electronic device, such as a television, a laptop computer, a monitor, a billboard, an Internet of Things (IoT) device, or the like. Alternatively, the display apparatus 1 may be a wearable device such as a smart watch, a watch phone, a glasses-type display, or a head-mounted display (HMD). Alternatively, the display apparatus 1 may be a portion of another device. For example, the display apparatus 1 may be a display unit of an electronic device. Alternatively, the display apparatus 1 may be a dashboard of a vehicle, a center fascia of a vehicle or a center information display (CID) disposed on a dashboard, a rear-view mirror display replacing a side mirror of a vehicle, and a display unit disposed on a back surface of a front seat as entertainment for a passenger on a back seat of a vehicle.

As shown in FIG. 1, the display apparatus 1 may include a display area DA and a peripheral area PA surrounding the display area DA. The display apparatus 1 may provide an image through an array of a plurality of pixels, which are two-dimensionally arranged in the display area DA. Each of the plurality of pixels of the display apparatus 1 is an area capable of emitting a certain color of light, and the display apparatus 1 may provide an image by using light emitted from the plurality of pixels. For example, each of the plurality of pixels may emit red, green, or blue light.

The display area DA may have a polygonal shape including a quadrangular shape, as shown in FIG. 1. For example, the display area DA may have a rectangular shape in which a horizontal length is shorter than a vertical length, a rectangular shape in which a horizontal length is longer than a vertical length, or a square shape. Alternatively, the display area DA may have various shapes, such as an oval shape or a circular shape.

The peripheral area PA is a non-display area that does not provide an image, and may entirely surround the display area DA. A driver or a main power line, which provides electrical signals or power to pixel circuits, may be arranged in the peripheral area PA. A pad, which is an area to which an electronic device or a printed circuit board may be electrically connected, may be arranged in the peripheral area PA.

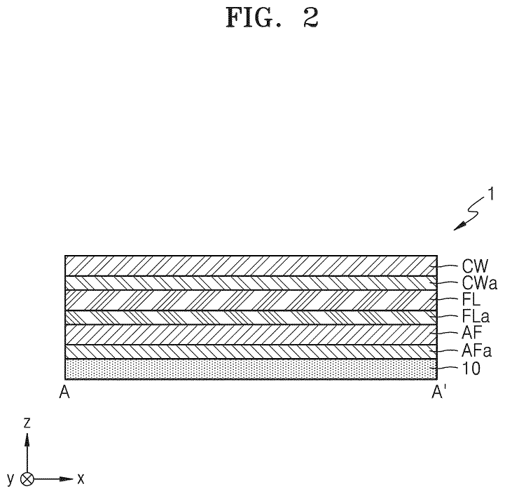

FIG. 2 is a cross-sectional view of the display apparatus 1 of FIG. 1, taken along a line A-A′. As shown in FIG. 2, the display apparatus 1 may include a display panel 10, an antenna film AF, a function layer FL, and a cover window CW. The display apparatus 1 may further include an antenna film adhesive layer AFa, a functional layer adhesive layer FLa, and a cover window adhesive layer CWa.

The display panel 10 may display an image. That is, an image provided by the display apparatus 1 may be implemented by the display panel 10. The display panel 10 may include a plurality of display elements, and the plurality of display elements may emit light. Accordingly, the display panel 10 may display an image through light emitted by the plurality of display elements.

In an embodiment, the display element may be an organic light-emitting diode including an organic emission layer. Alternatively, the display element may be a light-emitting diode (LED). The size of an LED may be in a micro scale or a nano scale. For example, the LED may be a micro-LED. Alternatively, the LED may be a nanorod LED. The nanorod LED may include gallium nitride (GaN). In an embodiment, a color converting layer may be disposed above the nanorod LED. The color converting layer may include quantum dots. Alternatively, the display element may be a quantum dot LED including a quantum dot emission layer. Alternatively, the display element may be an inorganic LED including an inorganic semiconductor.

The cover window CW may be disposed over the display panel 10. In particular, the cover window CW may be disposed on an upper surface of the display panel 10 (in a +z direction). Here, the ‘upper surface’ of the display panel 10 may be defined as a surface facing a direction in which the display panel 10 provides an image. According to an embodiment, the cover window CW may be arranged to cover the upper surface of the display panel 10. The cover window CW may protect the upper surface of the display panel 10. In addition, because the cover window CW forms the exterior of the display apparatus 1, the cover window CW may include a flat surface and a curved surface, which correspond to the shape of the display apparatus 1.

The cover window CW may have a high transmittance to transmit light emitted from the display panel 10, and may have a thin thickness to minimize the weight of the display apparatus 1. In addition, the cover window CW may have strong strength and harness to protect the display panel 10 from external impact. The cover window CW may be a flexible window. The cover window CW may protect the display panel 10 while being easily bent by an external force without the occurrence of cracks or the like.

The cover window CW may include glass, sapphire, or plastic. For example, the cover window CW may be an ultra-thin glass (UTG®) or colorless polyimide (CPI) of which the strength is strengthened by a method such as chemical strengthening, thermal strengthening, or the like. The cover window CW may have a structure in which a flexible polymer layer is disposed on one surface of a glass substrate, or may only include a polymer layer. An image displayed by the display panel 10 may be provided to a user through the cover window CW, which is transparent. That is, an image provided by the display apparatus 1 may be implemented by the display panel 10.

The antenna film AF may be between the display panel 10 and the cover window CW. In particular, the antenna film AF may be disposed over the display panel 10, and the cover window CW may be disposed over the antenna film AF. The antenna film AF may transmit, receive, or transmit and receive a wireless communication signal, for example, a radio frequency signal. The antenna film AF may include a plurality of antennas, a plurality of antenna lines, and a plurality of antenna pads. The plurality of antennas may transmit, receive, or transmit and receive in the same frequency band, or may transmit, receive, or transmit and receive in different frequency bands. The plurality of antennas, the plurality of antenna lines, and the plurality of antenna pads are described below.

In an embodiment, the function layer FL may be between the antenna film AF and the cover window CW. Accordingly, the function layer FL may be disposed over the antenna film AF, and the cover window CW may be disposed over the function layer FL.

In an embodiment, the function layer FL may be an optical functional layer that reduces the reflectance of light (e.g., external light) incident toward the display panel 10 from the outside. Accordingly, the function layer FL may improve the color purity of light emitted from the display panel 10. The function layer FL may include a polarizing film including a retarder and a polarizer. The retarder may include a λ/2 retarder or a λ/4 retarder.

In another embodiment, the function layer FL may be a protective layer that protects the display panel 10 from external impact. Accordingly, the function layer FL may include a polymer resin. For example, the function layer FL may include at least one of polyethersulfone, polyacrylate, polyetherimide, polyethylene naphthalate, polyethylene terephthalate, polyphenylene sulfide, polyimide, polycarbonate, and cellulose acetate propionate. Alternatively, the function layer FL may include a material such as glass or quartz.

In this case, each of a plurality of adhesive layers may be arranged between components of the display apparatus 1 to adhere one component to another component of the display apparatus 1. In particular, the antenna film adhesive layer AFa may be between the display panel 10 and the antenna film AF. The antenna film adhesive layer AFa may adhere the antenna film AF to the display panel 10. The functional layer adhesive layer FLa may be between the antenna film AF and the function layer FL. The functional layer adhesive layer FLa may adhere the function layer FL to the antenna film AF. The cover window adhesive layer CWa may be between the function layer FL and the cover window CW. The cover window adhesive layer CWa may adhere the cover window CW to the function layer FL.

Each of the antenna film adhesive layer AFa, the functional layer adhesive layer FLa, and the cover window adhesive layer CWa may include, for example, an adhesive member such as an optically clear adhesive (OCA) or a pressure sensitive adhesive (PSA). In an embodiment, the functional layer adhesive layer FLa and the cover window adhesive layer CWa may include the same material as the antenna film adhesive layer AFa. In another embodiment, the functional layer adhesive layer FLa and the cover window adhesive layer CWa may include different materials from that of the antenna film adhesive layer AFa. The antenna film adhesive layer AFa is described below in detail.

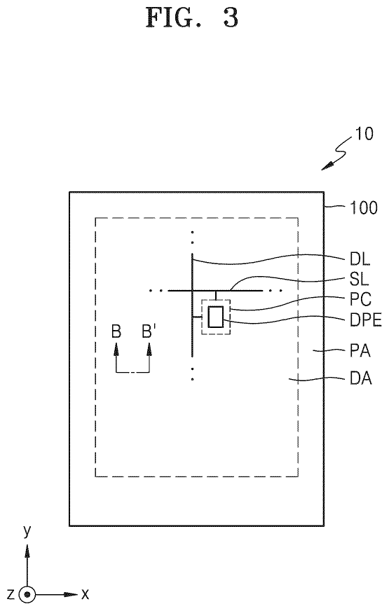

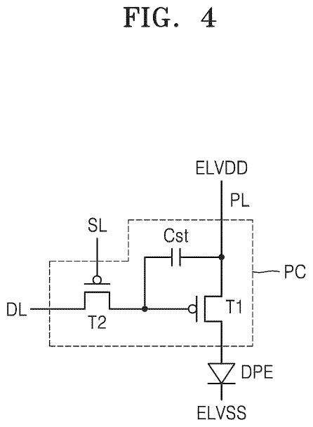

FIG. 3 is a schematic plan view of the display panel 10 of the display apparatus 1 according to an embodiment. FIG. 4 is an equivalent circuit diagram schematically illustrating a pixel circuit PC of the display panel 10 and a display element DPE connected to the pixel circuit PC. One display element DPE may correspond to one pixel, and the display element DPE may be an organic light-emitting diode.

The display panel 10 may include a substrate 100, the pixel circuit PC, a scan line SL, a data line DL, a driving voltage line PL, and the display element DPE. As described above, the display apparatus 1 includes the display panel 10, and the display panel 10 includes the substrate 100. That is, because the display apparatus 1 includes the substrate 100, the substrate 100 may also be seen to have the display area DA and the peripheral area PA. Hereinafter, for convenience, the substrate 100 is described as having the display area DA and the peripheral area PA.

The pixel circuit PC and the display element DPE may be arranged in the display area DA. The pixel circuit PC may include a driving transistor T1, a switching transistor T2, and a storage capacitor Cst. The display element DPE may emit red, green, or blue light, or may emit red, green, blue, or white light.

The switching transistor T2 may be connected to the scan line SL and the data line DL, and be configured to transfer, to the driving transistor T1, a data voltage or a data signal input to the data line DL, according to a scan voltage or a scan signal input to the scan line SL.

The storage capacitor Cst may be connected to the switching transistor T2 and the driving voltage line PL, and store a voltage corresponding to a difference between a voltage received from the switching transistor T2 and a first power voltage ELVDD supplied to the driving voltage line PL.

The driving transistor T1 may be connected to the driving voltage line PL and the storage capacitor Cst, and may control a driving current flowing from the driving voltage line PL to the display element DPE in accordance with a voltage value stored in the storage capacitor Cst. The display element DPE may emit light having a certain brightness according to the driving current. An opposite electrode (e.g., a cathode) of the display element DPE may receive a second power voltage ELVSS.

Although FIG. 4 shows that the pixel circuit PC includes two transistors and one storage capacitor, the pixel circuit PC may include three or more transistors.

A scan driver (not shown) providing a scan signal to the pixel circuit PC, a data driver (not shown) providing a data signal, and a power line (not shown) providing the first power voltage ELVDD or the second power voltage ELVSS may be arranged in the peripheral area PA. Also, a pad (not shown) may be arranged in the peripheral area PA, and a display circuit board may be electrically connected to the pad.

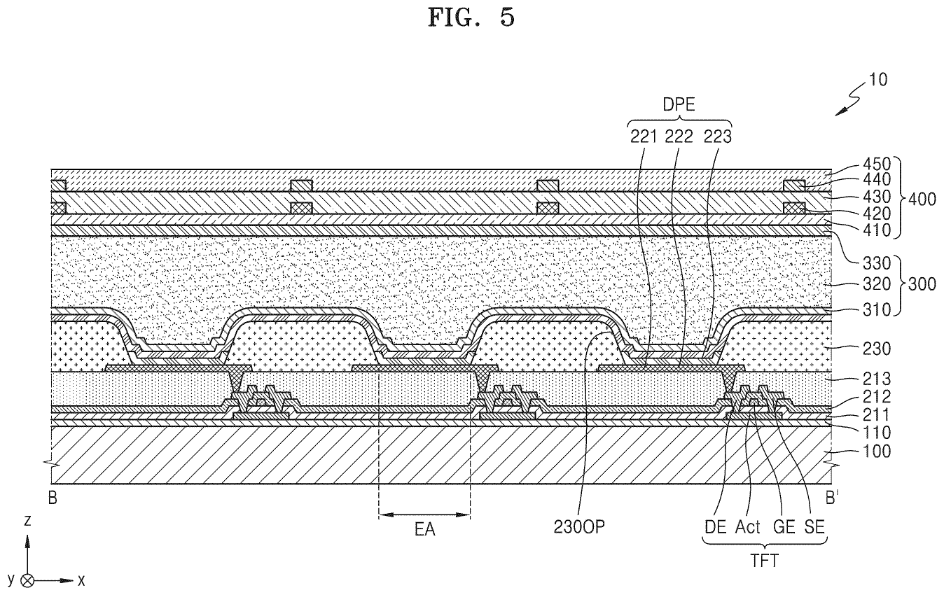

FIG. 5 is a schematic cross-sectional view of the display panel 10 of FIG. 3, taken along a line B-B′. As shown in FIG. 5, the display panel 10 may include the substrate 100, a transistor TFT, the display element DPE, an encapsulation layer 300, and a touch sensor layer 400.

The substrate 100 may include various materials which are flexible or bendable. For example, the substrate 100 may include glass, metal, or a polymer resin. Also, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin and a barrier layer including an inorganic material (for example, silicon oxide (SiO_{X}), silicon nitride (SiN_{X}), silicon oxynitride (SiO_{X}N_{Y}), or the like) arranged between the two layers, and various modifications may be made.

The display element DPE and the transistor TFT electrically connected to the display element DPE may be disposed above the substrate 100. One display element DPE may correspond to one pixel. For example, the display element DPE may be an organic light-emitting diode.

In particular, a plurality of transistors TFT may be disposed above the substrate 100. The plurality of transistors TFT may be electrically connected to a plurality of display elements DPE, respectively. The transistor TFT electrically connected to each display element DPE may be one transistor included in the pixel circuit PC described above with reference to FIGS. 3 and 4.

A buffer layer 110 including an inorganic material, such as silicon oxide (SiO_{X}), silicon nitride (SiN_{X}), or silicon oxynitride (SiO_{X}N_{Y}), or the like, may be arranged between the transistor TFT and the substrate 100. The buffer layer 110 may increase the smoothness of the upper surface of the substrate 100 or may prevent or minimize penetration of impurities from the substrate 100 or the like into a semiconductor layer Act of the transistor TFT.

As shown in FIG. 5, the transistor TFT may include the semiconductor layer Act, a gate electrode GE, a source electrode SE, and a drain electrode DE. FIG. 5 shows a top-gate type of the transistor TFT in which the gate electrode GE is disposed above the semiconductor layer Act with a gate insulating layer 211 therebetween, but the disclosure is not limited thereto. For example, the transistor TFT may be a bottom-gate type.

The semiconductor layer Act may be positioned on the buffer layer 110. The semiconductor layer Act may include a channel area, a source area, and a drain area, wherein the source area and the drain area are doped with impurities and respectively positioned on both sides of the channel area. At this time, the impurities may include an N-type impurity or a P-type impurity. The semiconductor layer Act may include amorphous silicon or polysilicon. In an embodiment, the semiconductor layer Act may include an oxide of at least one material selected from a group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). Also, the semiconductor layer Act may include a zinc-oxide-based material such as Zn oxide, In—Zn oxide, Ga—In—Zn oxide, or the like. In addition, the semiconductor layer Act may include an In—Ga—Zn—O (IGZO), In—Sn—Zn—O (ITZO), or In—Ga—Sn—Zn—O (IGTZO) semiconductor, which include a metal such as In, Ga, and Sn in ZnO.

The gate electrode GE may be disposed above the semiconductor layer Act to overlap at least a portion of the semiconductor layer Act. In particular, the gate electrode GE may overlap the channel area of the semiconductor layer Act. The gate electrode GE may include various conductive materials including molybdenum (Mo), Al, copper (Cu), titanium (Ti), or the like, and may have various layer structures. For example, the gate electrode GE may include a Mo layer and an Al layer, or may have a multi-layered structure of Mo layer/Al layer/Mo layer. In addition, the gate electrode GE may have a multi-layered structure including an ITO layer covering a metal material.

The gate insulating layer 211 between the semiconductor layer Act and the gate electrode GE may include an inorganic insulating material such as silicon oxide, silicon nitride, silicon oxynitride, aluminum oxide, titanium oxide, tantalum oxide, hafnium oxide, or the like. The gate insulating layer 211 may be a single layer or a multi-layer, each including the above-stated material.

The source electrode SE and the drain electrode DE may be respectively connected to a source area and a drain area of the semiconductor layer Act through contact holes. Each of the source electrode SE and the drain electrode DE may include various conductive materials including Mo, Al, Cu, Ti, or the like, and may have various layer structures. For example, each of the source electrode SE and the drain electrode DE may include a Ti layer and an Al layer, or may have a multi-layered structure of Ti layer/Al layer/Ti layer. In addition, each of the source electrode SE and the drain electrode DE may have a multi-layered structure including an ITO layer covering a metal material.

An interlayer insulating layer 212 on the gate insulating layer 211 may include an inorganic insulating material such as silicon oxide, silicon nitride, silicon oxynitride, aluminum oxide, titanium oxide, tantalum oxide, hafnium oxide, or the like. Also, the interlayer insulating layer 212 may be a single layer or a multi-layer, each including the above-stated material.

The gate insulating layer 211 and the interlayer insulating layer 212, which include the above inorganic insulating material, may be formed through chemical vapor deposition (CVD) or atomic layer deposition (ALD), but are not limited thereto.

The transistor TFT may be covered with an organic insulating layer 213. For example, the organic insulating layer 213 may cover the source electrode SE and the drain electrode DE. The organic insulating layer 213 is a planarization insulating layer, which may include a substantially flat upper surface. The organic insulating layer 213 may include a general commercial polymer such as poly(methyl methacrylate) (PMMA) or polystyrene (PS), a polymer derivative having a phenol group, and an organic insulating material such as an acrylic polymer, an imide polymer, an aryl ether polymer, an amide polymer, a fluorine polymer, a p-xylene polymer, a vinyl alcohol polymer, and a mixture thereof. In an embodiment, the organic insulating layer 213 may include polyimide.

The display element DPE may be disposed on the organic insulating layer 213. The display element DPE may emit red, green, or blue light. The display element DPE may be, for example, an organic light-emitting diode having a pixel electrode 221, an opposite electrode 223, and an intermediate layer 222 arranged therebetween and including an emission layer.

The pixel electrode 221 is electrically connected to the transistor TFT by being in contact with any one of the source electrode SE and the drain electrode DE through a contact hole formed in the organic insulating layer 213, as shown in FIG. 5. The pixel electrode 221 may include a transparent conductive layer including a transparent conductive oxide, such as ITO, In₂O₃, IZO, or the like, and a reflective layer including a metal, such as Al, Ag, or the like. For example, the pixel electrode 221 may have a triple-layered structure of ITO/Ag/ITO.

A pixel defining layer 230 may be disposed over the organic insulating layer 213. The pixel defining layer 230 defines a pixel by having an opening 230OP correspond to each of pixels, that is, the opening 230OP through which at least a central portion of the pixel electrode 221 is exposed. That is, at least a portion of the intermediate layer 222 may be positioned within the opening 230OP, and an emission area EA of the display element DPE may be defined by the opening 230OP. Also, as shown in FIG. 5, the pixel defining layer 230 prevents arcs or the like from being generated at edges of the pixel electrode 221 by increasing a distance between the edges of the pixel electrode 221 and the opposite electrode 223 above the pixel electrode 221. The pixel defining layer 230 may include, for example, an organic material such as polyimide or hexamethyldisiloxane (HMDSO).

The intermediate layer 222 may include a low-molecular-weight material or a polymer material. When the intermediate layer 222 includes a low-molecular-weight material, the intermediate layer 222 may have a structure in which a hole injection layer (HIL), a hole transport layer (HTL), an emission layer (EML), an electron transport layer (ETL), an electron injection layer (EIL), or the like are stacked in a single or complex structure, and may be formed by a method of vacuum deposition. When the intermediate layer 222 includes a polymer material, the intermediate layer 222 may have a structure including an HTL and an EML. At this time, the HTL may include poly(3,4-ethylenedioxythiophene) (PEDOT), and the EML may include a polymer material, such as a poly(p-phenylene vinylene) (PPV)-based polymer material, a polyfluorene-based polymer material, or the like. The intermediate layer 222 may be formed by a screen printing method, an inkjet printing method, a laser induced thermal imaging method, or the like. The intermediate layer 222 is not limited thereto and may have various structures. Also, the intermediate layer 222 may include an integral layer over a plurality of pixel electrodes 221, or may include a layer patterned to correspond to each of the plurality of pixel electrodes 221.

The opposite electrode 223 may be disposed on the intermediate layer 222. The opposite electrode 223 may be integrally formed over the plurality of display elements DPE to correspond to the plurality of pixel electrodes 221. Accordingly, the opposite electrode 223 may be commonly provided in the plurality of display elements DPE. The opposite electrode 223 may include a transparent conductive layer including ITO, In₂O₃, or IZO, and may also include a semi-transparent film including a metal such as Al, Ag, or the like. For example, the opposite electrode 223 may be a semi-transparent film including Mg or Ag.

The encapsulation layer 300 may be disposed on the display element DPE. For example, the encapsulation layer 300 may be disposed on the opposite electrode 223. Because the display element DPE may be easily damaged by moisture, oxygen, or the like from the outside, the encapsulation layer 300 may cover the display element DPE to protect the same.

The encapsulation layer 300 may include at least one inorganic encapsulation layer and at least one organic encapsulation layer. In an embodiment, as shown in FIG. 5, the encapsulation layer 300 may include a first inorganic encapsulation layer 310, an organic encapsulation layer 320, and a second inorganic encapsulation layer 330, which are sequentially stacked.

The first inorganic encapsulation layer 310 may cover the opposite electrode 223 and may include silicon oxide (SiO_{X}), silicon nitride (SiN_{X}), or silicon oxynitride (SiO_{X}N_{Y}), or the like. Other layers, such as a capping layer or the like, may also be between the first inorganic encapsulation layer 310 and the opposite electrode 223, when necessary. Because the first inorganic encapsulation layer 310 is formed along a structure therebelow, an upper surface of the first inorganic encapsulation layer 310 may not be flat, as shown in FIG. 5. The organic encapsulation layer 320 covers the first inorganic encapsulation layer 310, and unlike the first inorganic encapsulation layer 310, an upper surface of the organic encapsulation layer 320 may be formed substantially flat. In particular, the organic encapsulation layer 320 may have a substantially flat upper surface in a portion thereof corresponding to the display area DA. The organic encapsulation layer 320 may include one or more materials selected from a group consisting of polyethylene terephthalate, polyethylene naphthalate, polycarbonate, polyimide, polyethylene sulfonate, polyoxymethylene, polyarylate, and HMDSO. The second inorganic encapsulation layer 330 may cover the organic encapsulation layer 320 and may include silicon oxide (SiO_{X}), silicon nitride (SiN_{X}), or silicon oxynitride (SiO_{X}N_{Y}), or the like. The second inorganic encapsulation layer 330 may be in contact with the first inorganic encapsulation layer 310 at an edge of the second inorganic encapsulation layer 330, the edge being positioned outside the display area DA, and thus the organic encapsulation layer 320 may be prevented from being exposed to the outside.

When the encapsulation layer 300 includes the first inorganic encapsulation layer 310, the organic encapsulation layer 320, and the second inorganic encapsulation layer 330, even when cracks occur in the encapsulation layer 300, the cracks may be prevented from connecting between the first inorganic encapsulation layer 310 and the organic encapsulation layer 320 or between the organic encapsulation layer 320 and the second inorganic encapsulation layer 330. Accordingly, the formation of a path, through which external moisture, oxygen, or the like penetrates into the display area DA, may be prevented or reduced.

The touch sensor layer 400 may be disposed on the encapsulation layer 300. In particular, the touch sensor layer 400 may be disposed on the second inorganic encapsulation layer 330. The touch sensor layer 400 may obtain coordinate information according to an external input, for example, a touch event of an object such as a finger or a stylus pen.

The touch sensor layer 400 may include a plurality of touch conductive patterns and a plurality of touch insulating layers. For example, the touch sensor layer 400 may include a first touch insulating layer 410, a first touch conductive pattern 420, a second touch insulating layer 430, a second touch conductive pattern 440, and a third touch insulating layer 450. In an embodiment, the first touch insulating layer 410 may be a single layer or a multi-layer, each including an inorganic material such as silicon nitride (SiN_{X}), silicon oxide (SiO_{X}), or silicon oxynitride (SiO_{X}N_{Y}). In some embodiments, the first touch insulating layer 410 may include an organic material. In some embodiments, the first touch insulating layer 410 may be omitted.

The first touch conductive pattern 420 may be disposed on the first touch insulating layer 410 or the second inorganic encapsulation layer 330. In an embodiment, the first touch conductive pattern 420 may overlap the pixel defining layer 230. The first touch conductive pattern 420 may not overlap the opening 230OP of the pixel defining layer 230. The first touch conductive pattern 420 may include a conductive material. For example, the first touch conductive pattern 420 may include Mo, Al, Cu, Ti, or the like, and may include a multi-layer or a single layer, each including the above material. In an embodiment, the first touch conductive pattern 420 may have a structure (Ti/Al/Ti) in which a titanium layer, an aluminum layer, and a titanium are sequentially stacked.

The second touch insulating layer 430 may cover the first touch conductive pattern 420. The second touch insulating layer 430 may be a single layer or a multi-layer, each including an inorganic material such as silicon nitride (SiN_{X}), silicon oxide (SiO_{X}), or silicon oxynitride (SiO_{X}N_{Y}). In some embodiments, the second touch insulating layer 430 may include an organic material.

The second touch conductive pattern 440 may be disposed on the second touch insulating layer 430. In an embodiment, the second touch conductive pattern 440 may overlap the pixel defining layer 230. The second touch conductive pattern 440 may not overlap the opening 230OP of the pixel defining layer 230. In an embodiment, the second touch conductive pattern 440 may be connected to the first touch conductive pattern 420 through a contact hole provided in the second touch insulating layer 430. The second touch conductive pattern 440 may include a conductive material. For example, the second touch conductive pattern 440 may include Mo, Al, Cu, Ti, or the like, and may include a multi-layer or a single layer, each including the above material. In an embodiment, the second touch conductive pattern 440 may have a structure (Ti/Al/Ti) in which a titanium layer, an aluminum layer, and a titanium are sequentially stacked.

Each of the first touch conductive pattern 420 and the second touch conductive pattern 440 may include a plurality of touch sensing electrodes (not shown) for sensing touch inputs. In an embodiment, the plurality of touch sensing electrodes may sense an input in a mutual capacitance manner. In another embodiment, the plurality of touch sensing electrodes may sense an input in a self-capacitance method.

The third touch insulating layer 450 may cover the second touch conductive pattern 440. In an embodiment, the third insulating layer 450 may be a single layer or a multi-layer, each including an inorganic material such as silicon nitride (SiN_{X}), silicon oxide (SiO_{X}), or silicon oxynitride (SiO_{X}N_{Y}). In some embodiments, the third touch insulating layer 450 may include an organic material.

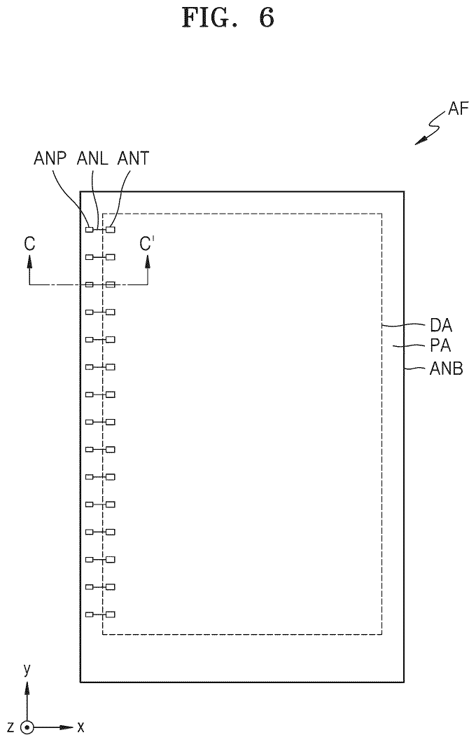

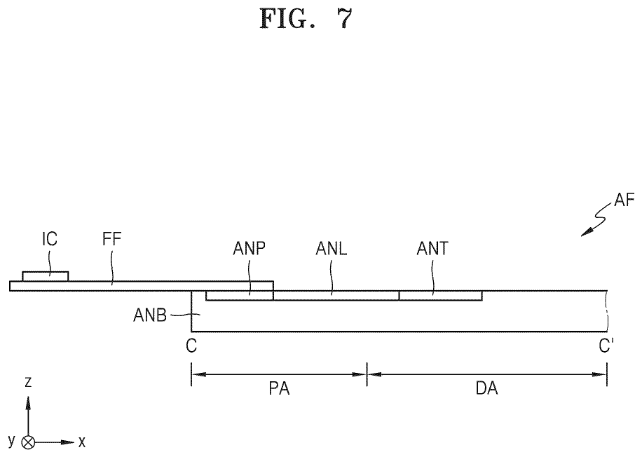

FIG. 6 is a schematic plan view of the antenna film AF of the display apparatus 1 according to an embodiment. FIG. 7 is a schematic cross-sectional view of the antenna film AF of FIG. 6, taken along a line C-C′. For convenience of explanation, the display area DA and the peripheral area PA are shown together in FIGS. 6 and 7. For convenience of explanation, a flexible printed circuit board FF and a driving chip IC are shown together in FIG. 7.

As shown in FIG. 6, the antenna film AF may include a base layer ANB, an antenna ANT, an antenna line ANL, and an antenna pad ANP. The antenna ANT and at least a portion of the antenna line ANL may be arranged in the display area DA. A remaining portion of the antenna line ANL and the antenna pad ANP may be arranged in the peripheral area PA.

The base layer ANB may include an insulating material having a certain dielectric constant. The base layer ANB may include a transparent film. For example, the base layer ANB may include at least one of an acrylic resin, a methacrylic resin, polyisoprene, a vinyl resin, an epoxy resin, a urethane resin, a cellulose resin, a siloxane resin, a polyamide resin, and a perylene resin.

The antenna ANT may be disposed on the base layer ANB, and a plurality of antennas ANT may be provided. In particular, the plurality of antennas ANT may be disposed on the base layer ANB to be spaced apart from each other in one direction. For example, the plurality of antennas ANT may be disposed on the base layer ANB to be spaced apart from each other in a first direction (e.g., an x direction or −x direction) or a second direction (e.g., a y direction or −y direction) crossing the first direction (e.g., the x direction or −x direction).

In an embodiment, the plurality of antennas ANT may be disposed on the base layer ANB to be spaced apart from each other by a distance of at least about 3.5 millimeters (mm) but not more than about 4 mm. In FIG. 6, the plurality of antennas ANT are shown as being arranged in the second direction (e.g., the y direction or −y direction) along one side of the antenna film AF, but the disclosure is not limited thereto. For example, the plurality of antennas ANT may be arranged in the first direction (e.g., an x direction or −x direction) along one side of the antenna film AF. FIG. 6 shows that the plurality of antennas ANT are arranged along one of four sides of the antenna film AF, but the disclosure is not limited thereto. For example, the plurality of antennas ANT may also be arranged along two of the four sides of the antenna film AF, or the plurality of antennas ANT may also be arranged along all four sides of the antenna film AF.

The antenna ANT may operate in a certain frequency band. The frequency band may include a resonant frequency. The resonant frequency may be 28 gigahertz (GHz). However, this is only an example, and the disclosure is not limited thereto. For example, the resonant frequency may be changed according to a frequency band of a signal to be communication. A gain of the antenna ANT may be 3 decibels-isotropic (dBi) or more, and a maximum gain of the antenna ANT may be 5 dBi.

The antenna ANT may have a width of at least about 2.9 mm but not more than about 3.3 mm in the first direction (e.g., the x direction or −x direction), and the antenna ANT may have a width of at least about 2.3 mm but not more than about 2.7 mm in the second direction (e.g., the y direction or −y direction). The width of the antenna ANT in the second direction (e.g., the y direction or −y direction) may be inversely proportional to the resonant frequency. However, this is only an example, and the disclosure is not limited thereto. For example, the width of the antenna ANT in the first direction (e.g., the x direction or −x direction) and the width of the antenna ANT in the second direction (e.g., the y direction or −y direction) may be determined by a dielectric disposed below the antenna ANT and a frequency band of a signal to be communicated.

The antenna ANT may include a conductive material. In particular, the antenna ANT may include carbon nanotubes, metal materials or metal alloys, or composite materials thereof, and may have a single-layered structure or a multi-layered structure in which Ti, Al, and Ti are sequentially stacked. For example, the metal materials may be silver (Ag), Cu, Al, gold (Au), or platinum (Pt). However, the disclosure is not limited thereto.

In an embodiment, the antenna ANT may further include at least one ground electrode disposed on a lower portion of the base layer ANB. However, this is only an example, and the ground electrode according to an embodiment is not limited thereto. For example, the ground electrode according to an embodiment may be the opposite electrode 223 of the display panel 10.

The antenna line ANL may be connected to one side of an antenna ANT, and a plurality of antenna lines ANL may be provided. In particular, the plurality of antenna lines ANL may be respectively connected to one side of the plurality of antennas ANT. The antenna line ANL may be connected to one side of one antenna ANT and extend toward the peripheral area PA. The antenna line ANL may supply power to the antenna ANT. The antenna line ANL may include the same material as the antenna ANT and may be formed through the same process as the antenna ANT.

The antenna pad ANP may be connected to the other side of one antenna line ANL, and a plurality of antenna pads ANP may be provided. In particular, the plurality of antenna pads ANP may be respectively connected to one side of the plurality of antenna lines ANL. The antenna pad ANP may be arranged in the peripheral area PA. That is, the antenna ANT may be arranged on one side of the antenna line ANL, and the antenna pad ANP may be arranged on another side of the antenna line ANL. The antenna ANT and the antenna pad ANP may be electrically connected to each other by the antenna line ANL.

The antenna pad ANP may be electrically connected to the flexible printed circuit board FF. The driving chip IC may be mounted on the flexible printed circuit board FF, and the flexible printed circuit board FF may transfer a signal generated by the driving chip IC to the antenna ANT. In particular, the driving chip IC may control an operation of the antenna ANT by providing a signal to the antenna ANT. For example, the driving chip IC may adjust the beam steering of the antenna ANT by adjusting power supplied to the antenna ANT, and may improve energy by focusing on a frequency signal in a particular direction. Also, a desired radiation pattern may be formed to improve radiation efficiency. In other words, the driving chip IC may transfer a signal to the antenna pad ANP through the flexible printed circuit board FF. Such a signal may be transferred to the antenna ANT by the flexible printed circuit board FF and the antenna pad ANP.

In an embodiment, the antenna ANT may have a mesh structure. That is, the antenna ANT may have a plurality of openings. As described above, the antenna ANT may be arranged in the display area DA, and the plurality of openings of the antenna ANT may respectively correspond to the plurality of display elements DPE disposed below the antenna ANT. In other words, the plurality of openings of the antenna ANT arranged in the display area DA may respectively correspond to the plurality of openings 230OP of the pixel defining layer 230. Accordingly, light generated by the plurality of display elements DPE disposed below the antenna ANT may be emitted to the outside of the display apparatus 1 through the plurality of openings of the antenna ANT.

In an embodiment, the antenna film AF may further include a dummy pattern (not shown). The dummy pattern may be arranged in the display area DA. In a plan view, the dummy pattern may surround the antenna ANT. The dummy pattern may reduce a difference in reflectance between a portion of the display area DA in which the antenna ANT is arranged and a portion of the display area DA in which the antenna ANT is not arranged. Because a dummy pattern is arranged in a portion of the display area DA where the antenna ANT is not arranged, the antenna ANT may not be visible from the outside.

The antenna ANT may be arranged in the display area DA, and the touch sensor layer 400 may be arranged in the display area DA, as described above with reference to FIG. 5. Accordingly, in a plan view, the antenna ANT may be arranged adjacent to the touch sensor layer 400. In particular, the antenna ANT may overlap a portion of the touch sensor layer 400 in a plan view, or the antenna ANT may be arranged adjacent to a portion of the touch sensor layer 400 in a plan view.

When the antenna ANT and the touch sensor layer 400 are arranged adjacent to each other, interference may occur between the antenna ANT and the touch sensor layer 400. That is, when each of the antenna ANT and the touch sensor layer 400 includes a conductive material, and the antenna ANT and the touch sensor layer 400 each including the conductive material are arranged adjacent to each other, interference may occur between the antenna ANT and the touch sensor layer 400.

Accordingly the performances of the antenna ANT and the touch sensor layer 400 may be reduced. In particular, a gain of the antenna ANT may be less than 3 dBi, and the sensing sensitivity (or touch sensitivity) of the touch sensor layer 400 may be reduced.

The reduction in the performances of the antenna ANT and the touch sensor layer 400 may vary depending on the antenna film adhesive layer AFa arranged between the antenna ANT and the touch sensor layer 400. In particular, when the antenna film adhesive layer AFa has a low relative permittivity, the reduction in the performances of the antenna ANT and the touch sensor layer 400 may be less than a case where the antenna film adhesive layer AFa has a high relative permittivity. Here, the relative permittivity is a value expressing a relative ratio of the dielectric permittivity of other materials based on the dielectric permittivity of vacuum. Permittivity is a physical property value representing the polarization amount that a dielectric generates in response to an external electric field applied thereto.

For example, when the antenna film adhesive layer AFa includes a rubber-based optically clear adhesive (OCA), for example, a styrene-based OCA, the reduction in the performances of the antenna ANT and the touch sensor layer 400 may be less than a case where the antenna film adhesive layer AFa includes an acrylate-based OCA. This is because influences of the antenna ANT and the touch sensor layer 400 on each other may be reduced as the relative permittivity of the antenna film adhesive layer AFa including the styrene-based OCA is lower than the relative permittivity of the antenna film adhesive layer AFa including the acrylate-based OCA.

A thickness of the antenna film adhesive layer AFa may vary depending on the relative permittivity of the antenna film adhesive layer AFa. In particular, when the relative permittivity of the antenna film adhesive layer AFa is high, the thickness of the antenna film adhesive layer AFa must be thick. That is, when the relative permittivity of the antenna film adhesive layer AFa is high, the thickness of the antenna film adhesive layer AFa must be thick enough to an extent that interference may not occur between the antenna ANT of the antenna film adhesive layer AFa and the touch sensor layer 400, and the performances of the antenna ANT and the touch sensor layer 400 may not be reduced. However, when the relative permittivity of the antenna film adhesive layer AFa is low, the thickness of the antenna film adhesive layer AFa may be thin. That is, when the relative permittivity of the antenna film adhesive layer AFa is low, interference may not occur between the antenna ANT and the touch sensor layer 400 even when the thickness of the antenna film adhesive layer AFa is thin, and thus the performances of the antenna ANT and the touch sensor layer 400 may not be reduced. Accordingly, the thickness of the antenna film adhesive layer AFa including the styrene-based OCA may be less than the thickness of the antenna film adhesive layer AFa including the acrylate-based OCA.

The antenna film adhesive layer AFa may be a cured product of an adhesive composition. The adhesive composition may be a rubber-based adhesive composition, for example, a styrene-based adhesive composition. Herein, the styrene-based adhesive composition refers to an adhesive composition including styrene or a derivative of styrene.

In an embodiment, the styrene-based adhesive composition may include styrene, polybutadiene, sulfurous ester, isopropenyl toluene, and methylphenylacetylene.

For example, polybutadiene may include at least one of cis-1,4-polybutadiene, trans-1,4-polybutadiene, and 1,2-polybutadiene. In detail, polybutadiene may be cis-1,4-polybutadiene.

Sulfurous ester may be an ester of sulfurous acid. That is, sulfurous ester may be a derivative of sulfurous acid in the form of an ester. For example, sulfurous ester may include at least one of sulfurous acid, cyclohexylmethyl dodecyl ester, sulfurous acid, cyclohexylmethyl heptyl ester, and sulfurous acid, cyclohexylmethyl pentadecyl ester. In detail, sulfurous ester may be sulfurous acid, cyclohexylmethyl dodecyl ester.

Isopropenyl toluene may include at least one of p-isopropenyl toluene, o-isopropenyl toluene, and m-isopropenyl toluene. Methylphenylacetylene may include at least one of 3-methylphenylacetylene, 2-methylphenylacetylene, and 4-methylphenylacetylene. In detail, isopropenyl toluene may be p-isopropenyl toluene.

In an embodiment, the styrene-based adhesive composition may include at least about 35 wt % but not more than about 50 wt % of styrene, at least about 10 wt % but not more than about 20 wt % of polybutadiene, at least about 15 wt % but not more than about 25 wt % of sulfurous ester, at least about 5 wt % but not more than about 15 wt % of isopropenyl toluene, and at least about 3 wt % but not more than about 10 wt % of methylphenylacetylene. Herein, a content of each component included in an adhesive composition may be based on the total component weight of the adhesive composition, and may be a result analysis by nuclear magnetic resonance (NMR) spectroscopy. The NMR spectroscopy is a method of measuring a sample to be analyzed by using radio frequency (RF) resonance, which causes rotational transitions of atomic nuclei.

The antenna film adhesive layer AFa may be formed by curing the styrene-based adhesive composition. For example, the antenna film adhesive layer AFa may be formed by heat-curing the styrene-based adhesive composition. Because a process of heat-curing an adhesive composition is a common process in forming an adhesive layer, detailed description thereof is omitted.

The antenna film adhesive layer AFa may have a low relative permittivity. The styrene-based adhesive composition includes styrene, isopropenyl toluene, and methylphenylacetylene, which include a benzene ring that may lower the polarity of molecules. Accordingly, the antenna film adhesive layer AFa formed by curing the styrene-based adhesive composition may have a low relative permittivity. In particular, the antenna film adhesive layer AFa formed by curing the styrene-based adhesive composition including the component ratio in the above range may have a relative permittivity of at least about 1.7 but not more than about 2.5. In detail, the antenna film adhesive layer AFa may have a relative permittivity of at least about 2.0 but not more than about 2.5.

Accordingly, the antenna film adhesive layer AFa may have a thin thickness. In particular, the antenna film adhesive layer AFa may have a thickness of at least about 50 μm but not more than about 150 μm. In detail, the antenna film adhesive layer AFa may have a thickness of at least about 50 μm but not more than about 100 μm. Even when the antenna film adhesive layer AFa has a thin thickness, interference does not occur between the antenna ANT and the touch sensor layer 400, and thus the performances of the antenna ANT and the touch sensor layer 400 may not be reduced.

When an adhesive layer includes an acrylate-based OCA, the adhesive layer may have a high relative permittivity. For example, the adhesive layer including the acrylate-based OCA may have a relative permittivity of at least about 2.7 but not more than about 4.0. Accordingly, when an antenna film adhesive layer includes the acrylate-based OCA, the antenna film adhesive layer should have a thickness of 150/or more.

However, the antenna film adhesive layer AFa of the display apparatus 1 according to an embodiment has a low relative permittivity of at least about 2.0 but not more than about 2.5. Accordingly, the antenna film adhesive layer AFa of the display apparatus 1 according to an embodiment has a thin thickness of at least about 50 μm but not more than about 100 μm. Even in this case, interference does not occur between the antenna ANT and the touch sensor layer 400, and thus the performances of the antenna ANT and the touch sensor layer 400 may not be reduced. That is, the antenna film adhesive layer AFa of the display apparatus 1 according to an embodiment may have a thin thickness and improve the reliability of the touch sensor layer 400 and the antenna ANT at the same time.

In an embodiment, the styrene-based adhesive composition may further include an antioxidant. For example, the antioxidant may include at least one of butylated hydroxytoluene, butylhydroxyanisole, ascorbic acid, sodium ascorbate, and tocopherol. In detail, the antioxidant may be butylated hydroxytoluene. However, the disclosure is not limited thereto. In an embodiment, the styrene-based adhesive composition may further include at least about 3 wt % but not more than about 10 wt % of the antioxidant.

In an embodiment, the styrene-based adhesive composition may further include a plasticizer. The plasticizer may include at least one of diethyl phthalate, dibutyl phthalate, butyl benzylphthalate, dibenzyl phthalate, alkyl phosphates, hydroxyethylated alkyl phenol, tricresyl phosphate, and triethyleneglycol diacetate. In detail, the plasticizer may be diethyl phthalate. However, the disclosure is not limited thereto. In an embodiment, the styrene-based adhesive composition may further include at least about 0.5 wt % but not more than about 2 wt % of the plasticizer.

### Experimental Examples

Hereinafter, the disclosure is described in more detail through experimental examples. However, the following experimental examples are for explaining the disclosure in more detail, and the scope of the disclosure is not limited by the following experimental examples. The following experimental examples may be appropriately modified or changed by those skilled in the art within the scope of the disclosure. The following experimental examples differ only in the components and contents of an adhesive composition of an antenna film adhesive layer, and other conditions are the same.

Table 1 shows the components and contents of an adhesive composition according to an embodiment. In particular, Table 1 shows the components and contents of an adhesive composition of Example 1.

TABLE 1

| | Contents |
|---|---|
| Components | (wt %) |
| styrene | 43.3 |
| cis-1,4-polybutadiene | 17.2 |
| sulfurous acid, cyclohexylmethyl | 19.0 |
| dodecyl ester | |
| p-isopropenyl toluene | 10.1 |
| 3-methylphenylacetylene | 5.2 |
| butylated hydroxytoluene | 4.2 |
| diethyl phthalate | 1.0 |

Referring to Table 1, the adhesive composition of Example 1 is a styrene-based adhesive composition. That is, the adhesive composition of Example 1 includes styrene, polybutadiene, sulfurous ester, isopropenyl toluene, and methylphenylacetylene.

In particular, the adhesive composition of Example 1 includes 43.3 wt % of styrene, 17.2 wt % of cis-1,4-polybutadiene, 19.0 wt % of sulfurous acid, cyclohexylmethyl dodecyl ester, 10.1 wt % of p-isopropenyl toluene, and 5.2 wt % of 3-methylphenylacetylene. The adhesive composition of Example 1 further includes 4.2 wt % of butylated hydroxytoluene and 1.0 wt % of diethyl phthalate.

Table 2 shows the components and contents of an adhesive composition according to a comparative example. In particular, Table 2 shows the components and contents of the adhesive composition of Comparative Example 1.

TABLE 2

| | Contents |
|---|---|
| Components | (wt %) |
| 2-ethylhexyl acetylate | 46.45 |
| isobornyl acrylate | 13.65 |
| octyl methacrylate | 37.80 |
| 2-hydroxy-2-metyl-1-phenyl-propan-1-one | 0.1 |
| 3-glycidoxypropyl trimethoxysilane | 2.0 |

Referring to Table 2, the adhesive composition of Comparative Example 1 is an acrylate-based adhesive composition. Herein, an acrylate-based adhesive composition refers to an adhesive composition including acrylate or a derivative of acrylate. In particular, the adhesive composition of Comparative Example 1 includes 46.45 wt % of 2-ethylhexyl acetylate (2-EHA), 13.65 wt % of isobornyl acrylate (IBOA), and 37.80 wt % of octyl methacrylate (OMA).

The adhesive composition of Comparative Example 1 further includes 0.1 wt % of 2-hydroxy-2-methyl-1-phenyl-propan-1-one (Irgacure 1173) and 2.0 wt % of 3-glycidoxypropyl trimethoxysilane (silane A 187). 2-hydroxy-2-methyl-1-phenyl-propan-1-one (Irgacure 1173) is included in the adhesive composition of Comparative Example 1 as a photo[olumerization initiator. 3-glycidoxypropyl trimethoxysilane (silane A 187) is included in the adhesive composition of Comparative Example 1 as an additive to adjust crosslinking and improve adhesion of an antenna film adhesive layer.

Table 3 shows the relative permittivity, thickness, and adhesive strength of antenna film adhesive layers included in display apparatuses according to an embodiment and a comparative example. In particular, Table 3 shows the relative permittivity, thickness, and adhesive strength of the antenna film adhesive layers of Example 1 and Comparative Example 1. The adhesive strength in Table is measured at room temperature. The antenna film adhesive layer AFa of Example 1 is manufactured by heat-curing the adhesive composition having the components and contents of Table 1, and the antenna film adhesive layer of Comparative Example 1 is manufactured by photocuring the adhesive composition having the components and contents of Table 2. Because a process of heat-curing an adhesive composition and a process of photocuring an adhesive composition are common processes in forming an adhesive layer, detailed descriptions thereof are omitted.

TABLE 3

| | | Comparative |
|---|---|---|
| | Example 1 | Example 1 |
| relative permittivity | 2.3 | t3.9 |
| thickness (μm) | 95 | 150 |
| adhesive strength | 2600 | 3098 |
| (gf/inch) | | |

Referring to Table 3, the antenna film adhesive layer AFa of Example 1 has a relative permittivity of 2.3, and the antenna film adhesive layer of Comparative Example 1 has a relative permittivity of 3.9. Accordingly, even when the antenna film adhesive layer AFa of Example 1 has a thickness of 95 μm, a gain of the antenna ANT is 3 dBi or more, and the performance of the touch sensor layer 400 is not reduced. On the contrary, the antenna film adhesive layer of Comparative Example 1 must have a thickness of 150 μm so that the gain of the antenna ANT is 3 dBi or more, and the performance of the touch sensor layer 400 is not reduced.

The antenna film adhesive layer AFa of Example 1 with a thickness of 95 μm has an adhesive strength of 2600 gf/inch. This is similar to the level of adhesive strength of 3098 gf/inch of the antenna film adhesive layer of Comparative Example 1 with a thickness of 150 μm. As the thickness of an adhesive layer increases, an adhesive strength thereof increases. For reference, the antenna film adhesive layer AFa of Example 1 has an adhesive strength of 2050 gf/inch at a thickness of 50 μm, and the antenna film adhesive layer AFa of Example 1 has an adhesive strength of 3200 gf/inch at a thickness of 150 μm. That is, the antenna film adhesive layer AFa of Example 1 may have a thin thickness and improve the reliability of the touch sensor layer 400 and the antenna ANT at the same time.

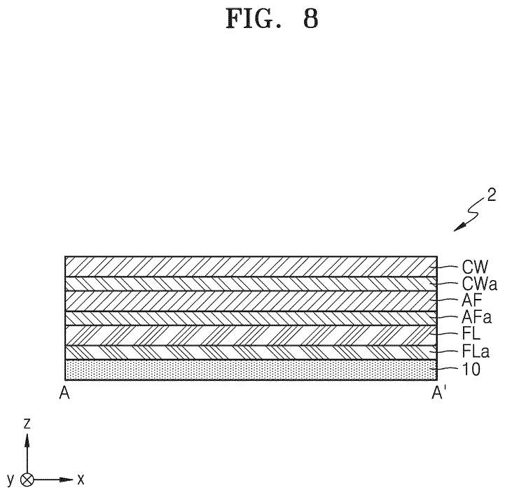

FIG. 8 is a schematic cross-sectional view of a display apparatus 2 according to another embodiment. The display apparatus 2 according to an embodiment is similar to similar to the display apparatus 1 described above with reference to FIGS. 1 to 7, and differences from the display apparatus 1 described above with reference to FIGS. 1 to 7 are mainly described hereafter. In FIG. 8, the same reference numerals as those in FIGS. 1 to 7 refer to the same members, and redundant descriptions thereof are omitted.

The display apparatus 1 according to the embodiment described above with reference to FIGS. 1 to 7 may include the display panel 10, the antenna film AF, the function layer FL and the cover window CW. As shown in FIG. 8, the display apparatus 2 according to an embodiment may also include the display panel 10, the antenna film AF, the function layer FL, and the cover window CW.

However, as shown in FIG. 8, in the display apparatus 2 according to an embodiment, the function layer FL may be between the display panel 10 and the antenna film AF. Accordingly, the function layer FL may be disposed over the display panel 10, the antenna film AF may be disposed over the function layer FL, and the cover window CW may be disposed over the antenna film AF. In this case, the antenna film adhesive layer AFa may be between the function layer FL and the antenna film AF. The antenna film adhesive layer AFa may adhere the antenna film AF to the function layer FL. The functional layer adhesive layer FLa may be between the display panel 10 and the function layer FL. The functional layer adhesive layer FLa may adhere the function layer FL to the display panel 10. The cover window adhesive layer CWa may be between the antenna film AF and the cover window CW. The cover window adhesive layer CWa may adhere the cover window CW to the antenna film AF.

Even in the case of the display apparatus 2 according to an embodiment, the antenna film adhesive layer AFa may be a cured product of a styrene-based adhesive composition. The styrene-based adhesive composition may include styrene, isopropenyl toluene, and methylphenylacetylene, which include a benzene ring that may lower the polarity of molecules. In particular, the styrene-based adhesive composition may include at least about 35 wt % but not more than about 50 wt % of styrene, at least about 10 wt % but not more than about 20 wt % of polybutadiene, at least about 15 wt % but not more than about 25 wt % of sulfurous ester, at least about 5 wt % but not more than about 15 wt % of isopropenyl toluene, and at least about 3 wt % but not more than about 10 wt % of methylphenylacetylene. Accordingly, the antenna film adhesive layer AFa formed by curing the styrene-based adhesive composition may have a low relative permittivity. Accordingly, the antenna film adhesive layer AFa may have a thin thickness.

Unlike the display apparatus 1 according to the embodiment described above with reference to FIGS. 1 to 7, the display apparatus 2 according to an embodiment may include the function layer FL between the display panel 10 and the antenna film AF, and thus the possibility of interference occurring between the antenna ANT and the touch sensor layer 400 may not be high. However, when the relative permittivity of the antenna film adhesive layer AFa is low or the thickness of the antenna film adhesive layer AFa is thick, the possibility of interference occurring between the antenna ANT and the touch sensor layer 400 may be further reduced.

That is, because the antenna film adhesive layer AFa has a low relative permittivity, even when the antenna film adhesive layer AFa has a thin thickness, the possibility of interference occurring between the antenna ANT and the touch sensor layer 400 may be further reduced. Accordingly, the antenna film adhesive layer AFa according to an embodiment may have a thin thickness and improve the reliability of the touch sensor layer 400 and the antenna ANT at the same time.

According to the embodiments described above, an adhesive composition that has a thin thickness and improves the reliability of a touch sensor and an antenna at the same time, and a display apparatus including the adhesive composition may be implemented. The scope of the disclosure is limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An adhesive composition comprising:
styrene;
polybutadiene;
sulfurous ester;
isopropenyl toluene; and
methylphenylacetylene,
wherein a cured product of the adhesive composition has a relative permittivity of at least about 2.0 but not more than about 2.5.

2. The adhesive composition of claim 1, wherein a content of the styrene is at least about 35 wt % but not more than about 50 wt %,
a content of the polybutadiene is at least about 10 wt % but not more than about 20 wt %,
a content of the sulfurous ester is at least about 15 wt % but not more than about 25 wt %,
a content of the isopropenyl toluene is at least about 5 wt % but not more than about 15 wt %, and
a content of the methylphenylacetylene is at least about 3 wt % but not more than about 10 wt %.

3. The adhesive composition of claim 1, wherein the polybutadiene comprises cis-1,4-polybutadiene,
the sulfurous ester comprises sulfurous acid, cyclohexylmethyl dodecyl ester,
the isopropenyl toluene comprises p-isopropenyl toluene, and
the methylphenylacetylene comprises 3-methylphenylacetylene.

4. The adhesive composition of claim 1, further comprising an antioxidant,
wherein a content of the antioxidant is at least about 3 wt % but not more than about 10 wt %.

5. The adhesive composition of claim 1, further comprising a plasticizer,
wherein a content of the plasticizer is at least about 0.5 wt % but not more than about 2 wt %.

6. A display apparatus comprising:
a display panel comprising a touch sensor layer;
an antenna film disposed over the display panel and comprising an antenna;
a functional layer disposed over the antenna film;
a cover window disposed over the functional layer; and
an antenna film adhesive layer between the display panel and the antenna film,
wherein the antenna film adhesive layer comprises a cured product of an adhesive composition, the adhesive composition comprising:
styrene;
polybutadiene;
sulfurous ester;
isopropenyl toluene; and
methylphenylacetylene,
wherein the antenna film adhesive layer has a relative permittivity of at least about 2.0 but not more than about 2.5 wt %.

7. The display apparatus of claim 6, wherein a content of the styrene is at least about 35 wt % but not more than about 50 wt %,
a content of the polybutadiene is at least about 10 wt % but not more than about 20 wt %,
a content of the sulfurous ester is at least about 15 wt % but not more than about 25 wt %,
a content of the isopropenyl toluene is at least about 5 wt % but not more than about 15 wt %, and
a content of the methylphenylacetylene is at least about 3 wt % but not more than about 10 wt %.

8. The display apparatus of claim 6, wherein the polybutadiene comprises cis-1,4-polybutadiene,
the sulfurous ester comprises sulfurous acid, cyclohexylmethyl dodecyl ester,
the isopropenyl toluene comprises p-isopropenyl toluene, and
the methylphenylacetylene comprises 3-methylphenylacetylene.

9. The display apparatus of claim 6, wherein the adhesive composition further comprises an antioxidant,
wherein a content of the antioxidant is at least about 3 wt % but not more than about 10 wt %.

10. The display apparatus of claim 6, wherein the adhesive composition further comprises a plasticizer,
wherein a content of the plasticizer is at least about 0.5 wt % but not more than about 2 wt %.

11. The display apparatus of claim 6, wherein, in a plan view, the touch sensor layer and the antenna are arranged adjacent to each other.

12. The display apparatus of claim 6, wherein the functional layer comprises a polarization film.

13. The display apparatus of claim 6, wherein
the functional layer comprises at least one of polyethersulfone, polyacrylate, polyetherimide, polyethylene naphthalate, polyethylene terephthalate, polyphenylene sulfide, polyimide, polycarbonate, and cellulose acetate propionate.

14. A display apparatus comprising:
a display panel comprising a touch sensor layer;
a functional layer disposed over the display panel;
an antenna film disposed over the functional layer and comprising an antenna;
a cover window disposed over the antenna film; and
an antenna film adhesive layer between the functional layer and the antenna film,
wherein the antenna film adhesive layer comprises a cured product of an adhesive composition, the adhesive composition comprising:
styrene;
polybutadiene;
sulfurous ester;
isopropenyl toluene; and
methylphenylacetylene,
wherein the antenna film adhesive layer has a relative permittivity of at least about 2.0 but not more than about 2.5 wt %.

15. The display apparatus of claim 14, wherein a content of the styrene is at least about 35 wt % but not more than about 50 wt %,
a content of the polybutadiene is at least about 10 wt % but not more than about 20 wt %,
a content of the sulfurous ester is at least about 15 wt % but not more than about 25 wt %,
a content of the isopropenyl toluene is at least about 5 wt % but not more than about 15 wt %, and
a content of the methylphenylacetylene is at least about 3 wt % but not more than about 10 wt %.

16. The display apparatus of claim 14, wherein the polybutadiene comprises cis-1,4-polybutadiene,
the sulfurous ester comprises sulfurous acid, cyclohexylmethyl dodecyl ester,
the isopropenyl toluene comprises p-isopropenyl toluene, and
the methylphenylacetylene comprises 3-methylphenylacetylene.

17. The display apparatus of claim 6, wherein the adhesive composition further comprises an antioxidant,
wherein a content of the antioxidant is at least about 3 wt % but not more than about 10 wt %.

18. The display apparatus of claim 14, wherein the adhesive composition further comprises a plasticizer,
wherein a content of the plasticizer is at least about 0.5 wt % but not more than about 2 wt %.

19. The display apparatus of claim 14, wherein, in a plan view, the touch sensor layer and the antenna are arranged adjacent to each other.

20. The display apparatus of claim 14, wherein the functional layer comprises a polarization film.

21. The display apparatus of claim 14, wherein the functional layer comprises at least one of polyethersulfone, polyacrylate, polyetherimide, polyethylene naphthalate, polyethylene terephthalate, polyphenylene sulfide, polyimide, polycarbonate, and cellulose acetate propionate.
